(19) United States
(12) Patent Application Publication
(10) Pub. No.: US 2021/0112674 A1
(43) Pub. Date: Apr. 15, 2021

(54) ADAPTER MODULE FOR CIRCUIT BOARD DEVICES AND HOUSING ASSEMBLY FOR SAME

(71) Applicant: Uber Technologies, Inc., San Francisco, CA (US)

(72) Inventors: Jon Ehlen, San Francisco, CA (US); Clark Shao, San Francisco, CA (US); Tingyu Tsang, San Francisco, CA (US); Yong Yan, San Francisco, CA (US)

(21) Appl. No.: 17/065,371

(22) Filed: Oct. 7, 2020

Related U.S. Application Data
(60) Provisional application No. 62/914,283, filed on Oct. 11, 2019.

(51) Int. Cl. H05K 5/02; H05K 5/00; H05K 7/20; H01R 33/94

(52) U.S. Cl. CPC H05K 5/0282; H05K 5/0221; H01R 33/94; H05K 7/20409; H05K 5/0026

(57) ABSTRACT

An adapter module includes a bottom housing segment, a top housing segment and a circuit board. The bottom housing segment is structured to mount to a topside of an external circuit board as a first type of component. The circuit board is structured to mount to an interior region of the bottom housing segment. The top housing segment is pivotably connected to the bottom housing segment to move between a closed position and an open position, where in the open position, the interior region can be exposed to allow for the one or multiple components to be accessed.

### RELATED APPLICATIONS

This application claims benefit of priority to Provisional U.S. Patent Application No. 62/914,283, filed on Oct. 11, 2019, entitled ADAPTER MODULE FOR CIRCUIT BOARD DEVICES AND HOUSING ASSEMBLY FOR SAME; the aforementioned priority application being hereby incorporated by reference in its entirety for all purposes.

### TECHNICAL FIELD

Examples pertain to adapter modules for circuit board devices and housing assembly for same.

### BACKGROUND

Circuit-board devices utilize a wide-variety of configurations. Motherboards, for example, house and interconnect the numerous components (e.g., processor, memory units, etc.) of a server or work station. Likewise, within the individual components, there exists sub-components that are typically interconnected by a component's circuit board. Such purposed circuit boards are typically deployed with a default configuration in which certain types of components or sub-components are pre-installed, or are provided for in the event of a subsequent installation or reconfiguration.

While some circuit board devices can be reconfigured from their initial default configuration, the ability of an owner or proprietor to reconfigure a circuit board device can be subject to pre-defined physical constraints. The physical constraints can include, for example, the layout (e.g., spacing, footprint, positioning of mounting holes) which the circuit board device provides for individual components that are mounted onto the circuit board device. As another example, the physical constraints can also include the mechanical and electrical configurations of one or more connector interfaces that are used by the circuit board device. Typically, the physical constraints are defined by a published standard from an industry consortium, and components of the circuit board device which conform to a particular standard can be said to be of a particular type. In many cases, the components of a circuit board device can be readily replaced, provided that the replacement component is of the same type as that of the existing component being replaced, or alternatively, of a compatible type as that of the existing component being replaced.

### BRIEF DESCRIPTION OF DRAWINGS

FIG. 1A and FIG. 1B illustrate a respective top and bottom isometric view of a housing assembly for an adapter module of a circuit board component, according to one or more examples.

FIG. 1C illustrates a front isometric view of a bottom housing segment for an adapter housing assembly, according to one or more examples.

FIG. 1D illustrates an adapter module that utilizes an adapter housing assembly as shown by FIG. 1A through FIG. 1C, according to one or more examples.

FIG. 1E and FIG. 1F illustrate respective top and bottom isometric views of an adapter module as shown by FIG. 1D, in an open orientation, according to one or more examples.

FIG. 1G is a front isometric view of an assembled adapter module in a closed orientation, according to one or more examples.

FIG. 1H and FIG. 1I include top and bottom views of an integrated circuit board device that can couple to an adapter housing module of FIG. 1D, according to one or more examples.

FIG. 1J and FIG. 1K illustrate closeups of regions A and B, respectively, of FIG. 1H, according to one or more examples.

FIG. 1L illustrates a top view of a portion of the circuit board device shown by C-C of FIG. 1H, according to one or more examples.

FIG. 1M illustrates an isometric view of a component latch used with the integrated circuit device of FIG. 1H and FIG. 1I, according to one or more examples.

### DETAILED DESCRIPTION

An example adapter module includes a bottom housing segment, a top housing segment and an internal electrical interface (e.g., internal circuit board) to receive other components (e.g., memory components). In examples, the bottom housing segment is structured to mount to a topside of an external circuit board (e.g., motherboard) as a first type of component. The interior electrical interface is structured to mount to an interior region of the bottom housing segment, where one or more components of a second type may be received. The top housing segment may be pivotably connected to the bottom housing segment to move between a closed position and an open position, and in the open position, the interior region can be exposed to allow for components of the second type to be accessed.

In many examples, an adapter module is provided for motherboards, to enable memory components of a first-type to be replaced on the motherboard with memory components of a second type. In specific examples, an adapter module is provided to enable an operator (e.g., engineer or technician) to replace a U.2 type memory component on a motherboard with one or more M.2 memory components. In examples, the adapter module can utilize the footprint and electrical interface of the default component (e.g., U.2 type memory component) as provided on a motherboard, while allowing the operator to substitute another type of memory component (e.g., M.2 type memory component) which could not otherwise be accommodated as a replacement for the original memory component. In context of a server, or multiple servers of a server rack, some examples as described enable or promote use of M.2 type memory components on motherboards that are otherwise designed or configured to utilize U.2 type memory components.

Additionally, some examples include a latch component to connect a component to a circuit board. In such examples, the latch component includes a base structured to attach to a circuit board, and a rotatable pivot structure that is positioned to extend vertically within a slot formed in the component when the base structure is attached. The latch component may also include a latch arm that extends laterally over the component of the circuit board, where the latch arm includes a base segment that joins or attaches to the pivot structure. In examples, the pivot structure includes one or more mechanisms to guide rotation of the pivot structure between a set range that coincides with the latch arm being pivoted between an engaged and an unengaged position.

Still further, other examples include a circuit board device that includes a circuit board, a component mounted on the circuit board, and a component latch that is attached to the circuit board. In examples, the component latch includes a rotatable pivot structure that extends vertically within a slot formed in the component. The component latch also includes a latch arm latch arm is configured to extend laterally over a top surface of the component, as well as a base segment that joins or attaches the latch arm to the pivot structure. In examples, the pivot structure may include one or more mechanisms to guide rotation of the pivot structure between a set range that coincides with the latch arm being pivoted between an engaged position where the component is retained, and an unengaged position where the component can be accessed and removed.

Among other benefits, examples as described enable an operator to access a component retained by a component latch from a topside of the underlying circuit board. Moreover, examples enable use of latches which require a minimal footprint on the underlying circuit board.

Adapter Housing Assembly

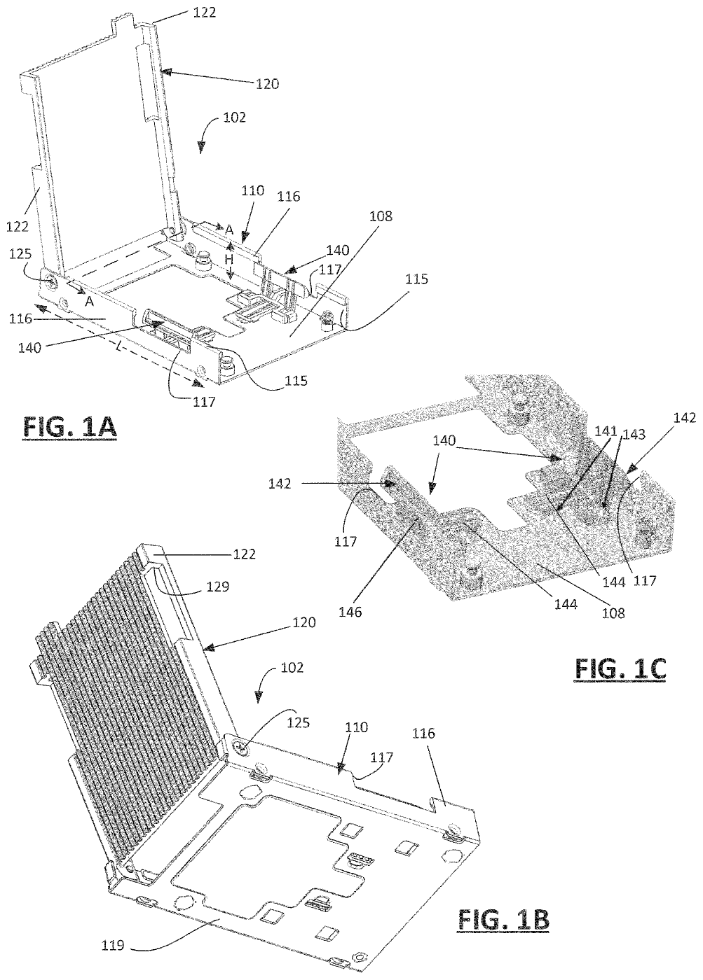

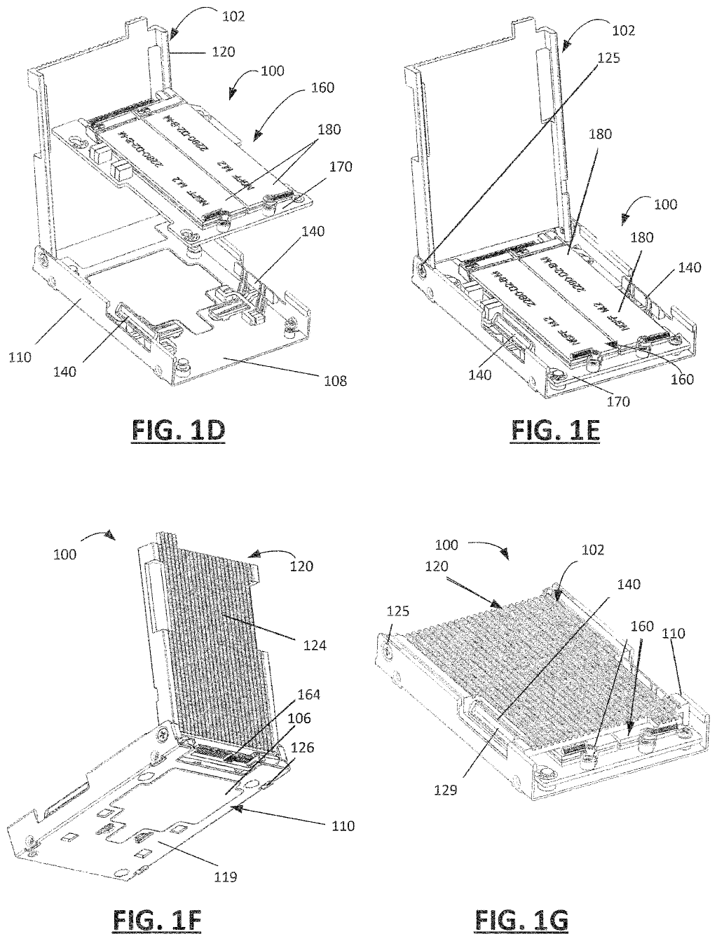

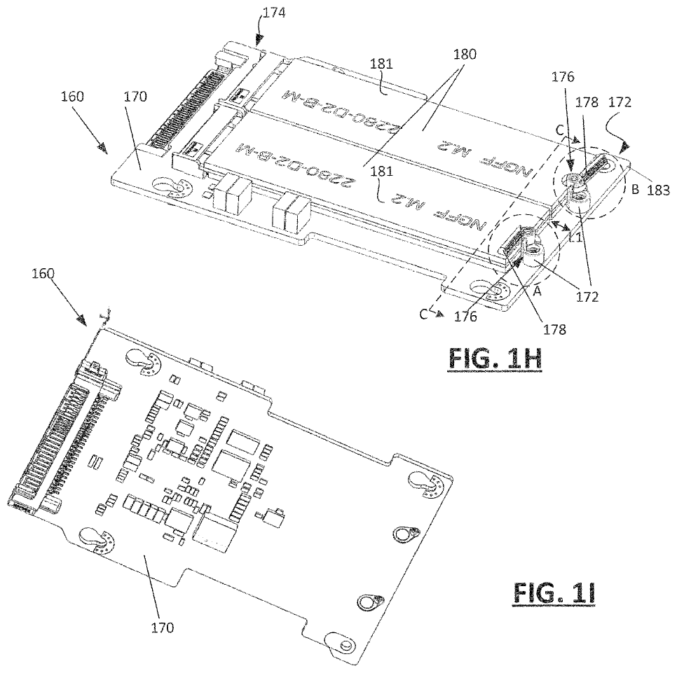

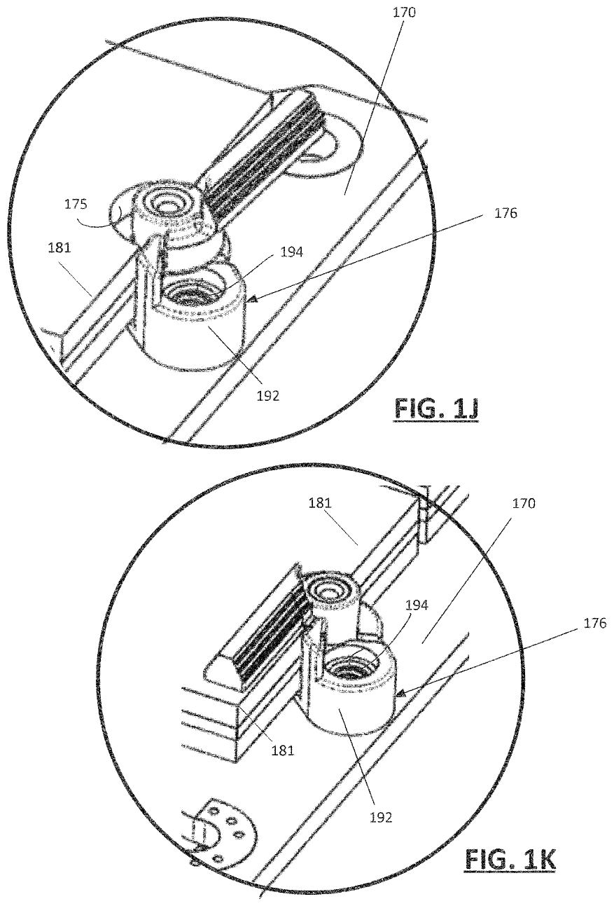

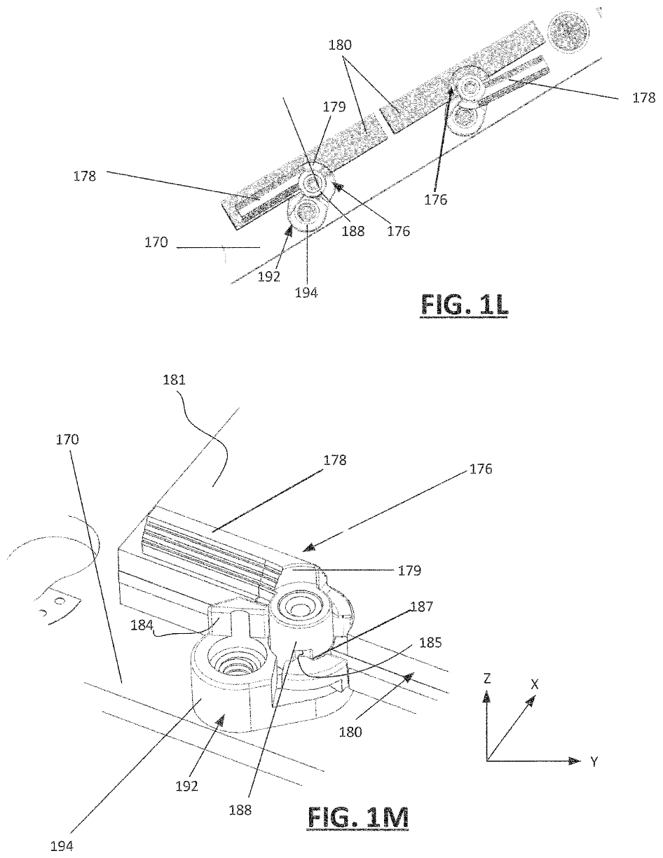

FIG. 1A and FIG. 1B illustrate a respective top and bottom isometric view of a housing assembly for an adapter module of a circuit board component, according to one or more examples. FIG. 1C illustrates a front isometric view of a bottom housing segment for an adapter housing assembly, according to one or more examples. As described by examples of FIG. 1A through FIG. 1C, an adapter housing assembly 102 is structured to retain a circuit board device of a first type while conforming to physical constraints that are predefined for circuit board devices of a second type. The adapter housing assembly 102 can be structured based on a predetermined form factor (e.g., overall dimension and footprint, positioning of mounting holes, etc.) that is associated with a component of a first type, while the adapter housing assembly 102 is structured to receive and retain a circuit board device having one or multiple circuit board devices of another type. By way of example, the adapter housing assembly 102 can be structured to receive one or multiple M.2 memory components while the adapter housing assembly 102 is dimensioned and structured to be received on an underlying external circuit board as a U.2 type memory device.

In examples, the adapter housing assembly 102 includes a bottom housing segment 110, and a top housing segment 120 that is pivotably connected the bottom housing segment 110. The bottom housing segment 110 includes a base panel 108, and opposing lateral sidewalls 116 which extend a length (L) of the bottom housing segment 110. The lateral sidewalls 116 can extend a height (H) from an interior of the base panel 108 to at least partially define an interior region 115 in which one or more circuit board devices can be retained. The bottom housing segment 110 can also include mounting holes and/or other features to receive and/or extend mechanical fasteners or connectors to the external motherboard, so as to enable an underside 119 of the bottom housing segment 110 to mount onto a topside of the external motherboard. The various physical configurations, such as the dimensions and mounting pin configuration of the bottom housing segment can be determined from a target form factor or specification, as described with other examples.

The top housing segment 120 can be pivotably connected (e.g., hinge-connected) to the bottom housing segment 110 to pivot between an open position and a closed position. The top housing segment 120 can include, for example, lateral sidewalls 122 which extend a length of the top housing segment 120. When in the open position, some examples provide that the top housing segment 120 can be extended to a position that is at or about 90 degrees from a reference plane that is parallel to the bottom housing segment 110. Depending on implementation, the range by which the top housing segment 120 can pivot can be more or greater than 90 degrees.

When in the top housing segment 120 is in the open position, an operator is given sufficient room to insert and/or remove (i) the circuit board device (see FIG. 1D and FIG. 1E) and/or components mounted onto the circuit board device. Among other advantages, examples allow for the top housing segment 120 to be manipulated to an open position while the bottom housing segment 110 is secured to an external motherboard, to enable inspection, repair and/or replacement of the circuit board device and/or components mounted thereon without removal of the external motherboard from a remainder of the computer. The lateral sidewalls 122 of the top housing segment 120 may be dimensioned by length and/or width to fit within length- and width-wise spans of the bottom housing segment 110 when in the closed position.

In examples, the top housing segment 120 is connected to the bottom housing segment 110 by one or more hinge connections 125. In an example, the lateral sidewalls 122 of the top housing segment 120 can include openings that align with corresponding openings of the lateral sidewalls 116 of the bottom housing segment 110. Each of the aligned openings can retain a connecting member that enables the top housing segment 120 to pivot between the open and closed positions.

As shown by FIG. 1A and FIG. 1C, the bottom housing segment 110 can include a pair of latches 140 positioned to oppose one another along a width-wise axis of the bottom segment. Each latch 140 can be structured to include a base portion 144 that is structured to secure to the base panel 108, and a moveable latch member 142 that extends vertically upward from the base portion 144. The base panel 108 of the bottom housing segment 110 can include, for example, opening(s) 106 and retention structures 126 (see FIG. 1F) that are aligned and structured to receive and engage corresponding retention structures (e.g., clasp 141, insert 143) of the individual latches 140, so as to anchor the respective base portions 144 to the bottom housing segment 110.

In examples, each latch 140 is structured to enable the corresponding latch member 142 to be moved inward (or outward), under bias, to enable a front end of the top housing segment 120 to latch and unlatch to the bottom housing segment 110. Each latch member 142 can include a retention structure 146 that can be made to engage, under bias, a latch opening 129 or structure of the top housing segment 120. In some examples, the retention structures 146 correspond to protrusions that extends outward from the latch member 142 to engage a suitably dimensioned latch opening 129 formed as part of a corresponding lateral surface region of the top housing segment 120. In the closed position, the retention structures 146 can be received within the respective latch openings 129 of the top housing segment 120. To move the top housing segment 120 into the open position, an operator can manipulate each latch members 142 inward toward one another to disengage the respective retention structure 146 from the corresponding latch opening 129 of the top housing segment 120. In examples, the bottom housing segment 110 includes a pair of access openings 117 that align with the latch openings 129 of the top housing segment 120, to allow an operator to access and manipulate the latch members 142 inward to latch and unlatch the front end of the top housing segment 120. Once the retention structures 146 are moved inward to disengage from the latch openings 129, the front end of the top housing segment 120 can be pivoted away from the bottom housing segment 110 into the open position.

Likewise, an operator may manipulate the latch members 142 inward again to enable the top housing segment 120 to be moved into the closed position, where the latch openings 129 are aligned with corresponding access openings 117 and retention structures 146 of the bottom housing segment 110. Once aligned, the operator can release the latch members 142, where the bias causes the retention structures 146 to move outward and engage the respective latch openings 129.

Adapter Module

FIG. 1D illustrates an adapter module that utilizes adapter housing assembly 102, according to one or more examples. As shown, an adapter module 100 may be formed by combining the adapter housing assembly 102 with a circuit board device 160. The circuit board device 160 can include a circuit board 170 on which one or more memory components 180 are mounted. With the top housing segment 120 in the open position, the circuit board device 160 can be moved from a top-down orientation into the interior region 115 (see FIG. 1A) of the bottom housing segment 110. In one implementation, the circuit board device 160 may be positioned over the respective base portions of the latches 140, before the circuit board device 160 is slid rearward into a seated position within the interior region 115 of the adapter housing assembly 102.

In some examples, when the adapter module 100 is mounted on an external circuit board device or other computing environment, the memory components 180 can be subsequently accessed by an operator from above, while the adapter module 100 remains mounted onto its computing environment. Thus, an operator may be able to inspect, repair or replace the components 180 of the adapter module 100, while the adapter module 100 remains mounted in its computing environment, thereby saving considerable time and effort for the operator.

FIG. 1E and FIG. 1F illustrate respective top and bottom isometric views of adapter module 100 in an open orientation, according to one or more examples. As shown by examples of FIG. 1E and FIG. 1F, the assembled adapter module 100 may include circuit board device 160 seated within the adapter housing assembly 102. When in an open orientation, the top housing segment 120 can be pivoted into an upright position, so as to enable an operator to access the components 180.

According to examples, the placement of the adapter module 100 can compress the base portion 144 (see FIG. 1C) of each latch 140 (see FIG. 1C), causing the circuit board device 160 to be in active contact with the latches 140 while being seated within the bottom housing segment 110. The bottom housing segment can include opening 106 and retention structures 126. Additionally, as shown by FIG. 1F, the underside 119 of the bottom housing segment 110 may provide an external connector 164 that conforms to a connector type used by the target device to communicate with other components on, for example, the external circuit board device. Accordingly, the external connector 164 is mateable a corresponding connector of the external circuit board or computing environment. The external connector 164 may be configured in accordance with a corresponding electrical component of a target device type. Thus, for example, an overall dimension of the external connector 164, as well as a pin configuration may conform to a specification for a connector type that is utilized by the target device type. The bottom housing segment 110 may include an opening that is dimensioned and positioned to enable the external connector 164 to be electrically mated on an external circuit board or other computing environment. As described in more detail, the circuit board 170 may integrate an electrical interface to enable an output signal generated by the individual components 180 to be transferred to the external circuit board device or computing environment via the external connector 164. Likewise, the integrated electrical interface of the circuit board 170 may configure incoming signals received by the external connector 164 for component connectors of the individual components 180.

FIG. 1G is a front isometric view of the assembled adapter module 100 in a closed orientation, according to one or more examples. The adapter module 100 in the closed orientation may coincide with the top housing segment 120 being in the closed position. For example, the top housing segment 120 may be manipulated to pivot about the hinge connection 125 from the open position to the closed position. In the closed position, the top housing segment 120 may be partially contained within the interior region 115 (see FIG. 1A) of the bottom housing segment 110, and the latch members 142 (see FIG. 1C) may be engaged with the latch openings 129 (see FIG. 1C). In the closed orientation, the exterior surface 124 of the top housing segment 120 provides an exterior facade for the adapter module 100. As described with other examples, the operation of the circuit board device 160 within the confine of the adapter housing assembly 102 can result in heat generation. In examples, the top housing segment 120 can be structured as a heat-sink to dissipate heat that is generated as a result of the operation of the adapter module 100.

With reference to FIG. 1D, FIG. 1E. FIG. 1F and FIG. 1G, examples recognize that when the adapter module 100 is operated on an external circuit board or computing environment, the resulting heat generated by the one or more components 180 can be damaging. In examples, the adapter housing assembly 102 includes a heat-dissipation system by which heat generated from the circuit board device 160 can be drawn out of the interior region 115 of the adapter housing assembly 102. In some examples, the top housing segment 120 can include external surface features which enable the top housing segment 120 to act as a heat sink for heat captured within the interior region 115. In examples, an external surface 124 of the top housing segment 120 can include ridges which extend lengthwise along the width of the top housing segment. As an addition or variation, the top housing segment 120 can include fins, channels or other heat-dissipation mechanisms which can leverage surrounding air and/or applied airflow to dissipate heat away from the adapter housing assembly 102. To promote use of the top housing segment 120 as a heat sink, the top housing segment 120 can be formed from thermally-conductive material, such as aluminum or copper.

The adapter housing assembly 102 may also include thermal material within the interior region 115 for purpose of transferring accumulated heat to the top housing segment 120. In examples, the adapter housing assembly 102 can include thermal pads which can be positioned, for example, on an underside of the top housing segment 120 to contact heated elements within the interior region 115.

As an addition or variation, each of the latches 140 can be formed from thermally-resistive material (e.g., nylon, polymer, etc.). When the circuit board device 160 is seated within the bottom segment, the latches 140 may be forced into contact with the circuit board 170. When the top housing segment 120 is moved into the closed position, portions of the latches 140 may further contact the top housing segment 120. The latches 140 may heat with the increase in temperature of the interior region 115, and the heat accumulated with the material of the latches 140 (as well as with thermal pads) can be transferred to the top housing segment 120, where it is dissipated.

In some examples, the adapter module 100 is manufactured as a complete assembly that integrates the circuit board device 160 within the adapter housing assembly 102. In such examples, the operator can replace a target component in a given computing environment with the preassembled adapter module 100. Subsequently, if the memory components 180 of the adapter module 100 need inspection, repair or replacement, the operator can access the components without removing the adapter module 100 from its connected environment. For example, an operator may initially mount the adapter module 100 on a topside of a motherboard, then subsequently access the memory components 180 retained within the adapter housing assembly 102 from a topside direction, such that the adapter module 100 may be accessed without removal from its connected environment.

In variations, the adapter housing assembly 102 may be manufactured separately from the circuit board device 160. In such examples, an operator may combine the adapter housing assembly 102 with the circuit board device 160 to form adapter module 100. The circuit board 170 may, for example, be preconfigured to retain memory components 180 of a desired type (e.g., M.2 type connector). In some examples, the circuit board device 160 may be provided to the operator in the form of a kit which the operator can integrate with the adapter housing assembly 102.

Still further, in some variations, the adapter housing assembly 102 may be pre-mounted onto a given computing environment (e.g., motherboard), and the circuit board 170 and/or the components 180 can be subsequently added to the adapter housing assembly 102 while it is mounted. In such examples, the operator can assembly the adapter module 100 while the adapter housing assembly 102 is mounted on a given computing environment. In other variations, the circuit board device 160 can be manufactured or pre-assembled as an integrated circuit board device for use with the adapter housing assembly 102, and the circuit board device 160 and the adapter housing assembly 102 can be combined to form the adapter module 100.

Circuit Board Device

FIG. 1H and FIG. 1I include top and bottom views of integrated circuit board device 160, according to one or more examples. The circuit board device 160 includes one or more components 180 which are mounted onto the circuit board 170, with a respective top external surface 181 being accessible. The circuit board 170 may be referenced by a front region 172 and a rear region 174, with the front region 172 including component latches 176 to retain the components 180, and the rear region 174 providing an electrical interface for enabling an external component communicate with the components 180.

Depending on implementation, the circuit board device 160 may be preassembled (e.g., manufactured as assembly), or the circuit board device 160 may be assembled by an operator. In examples, the component latches 176 enable an operator to attach and detach components 180 to the circuit board 170 for purpose of assembling the circuit board device 160. Additionally, when the adapter module 100 is mounted into a computing environment, the component latches 176 can be individually manipulated by an operator from a topside (or in a top-bottom) orientation for purpose of securing or removing a corresponding component 180. In some examples, each of the component latches 176 include corresponding retention arms 178 which can pivot over a top surface 181 of the corresponding component 180 between engaged and unengaged positions.

In examples, the circuit board 170 is configured (i) to be received by the adapter housing assembly 102, and (ii) to receive a particular type of component 180, such as a particular type of M.2 memory component. In some examples, the dimensions and layout of the circuit board 170 may match those of the bottom housing segment 110, so that the circuit board 170 can be received within the interior region 115 of the bottom housing segment 110. Additionally, the circuit board can be preconfigured such that mounting holes and other retention features of the circuit board 170 are aligned with corresponding structures and features of the base panel 108.

In examples, the circuit board 170 also includes an electrical interface for allowing an external component to interface with the components 180. The electrical interface can include component connectors for components 180, the external connector 164, and trace elements and/or embedded logic. The resulting electrical interface can extend connectivity between the component connectors of components 180 and the external connector 164 (see FIG. 1F). In examples, the trace elements and/or embedded logic may be structured to implement a signal format conversion to convert (i) a format of signals received from an external device (via the external connector 164) into a format that can be received and processed by the components 180; and (ii) a format of signals transmitted from one or both components 180 into a format that can be received and transmitted to an external device via the external connector 164. In examples, the signal conversion that is implemented by the trace elements and embedded logic of the circuit board 170 can include mapping signal lines between the different pin layouts used by a standard or protocol of the external connector 164 (which is externally accessed) with the signal line layout used by the components 180. Still further, the trace elements and embedded logic may also perform logical operations and signal processing steps which may otherwise be required or desired for the signal conversion. In examples, the trace elements may further be combined with processing and memory resources to implement the signal conversion process and/or enable other functions, such as enhanced data rate transfer.

In examples, an overall dimension of the circuit board 170 may be constrained by, for example, the dimensions or form factor of the target device (which may be specified by an industry standard specification), as well as the available space on the computing environment where the adapter module 100 is to be mounted. As shown, a substantial portion of the available space on the circuit board 170 may also be occupied by the components 180, thus limiting the available real-estate of the circuit board for carrying trace elements and other resources for implementing logic (e.g., such as logic to implement the conversion process). In recognition of the limited amount of circuit board area available for implementing signal format conversion and other logic, some examples provide for the circuit board device 160 to include design and layout configurations that are selected to increase the amount of circuit board area that is available in the rear region 174, where the component connector(s) and external connector 164 are provided. The added circuit board area can facilitate inclusion trace elements and logic for performing signal format conversion and other logic.

To increase the available area of the circuit board 170 in the rear region 174, some examples provide for the layout of the circuit board to minimize a segment of the circuit board 170 that extends beyond the front-most edge 183 of the component 180. As shown with FIG. 1H, examples provide for the circuit board 170 to have a layout in which a length (L1) of the front-most segment of the circuit board that is unoccupied to be about equal to a dimension of a footprint of an individual component latch 176. Still further, the length (L1) can be implemented to be the minimum length required to support the component latches 176

Component Latch

FIG. 1J and FIG. 1K illustrate closeups of regions A and B, respectively, of FIG. 1H, showing component latches 176 for circuit board device 160 in alternative positions. In an example of FIG. 1J, the latch arm 178 extends laterally over a region of the circuit board that is adjacent to the component 180, so that the latch arm 178 does not engage the top surface 181 of the component 180. In an example of FIG. 1K, the latch arm 178 is shown in an engaged position, where the latch arm 178 extends laterally over a front edge portion of the corresponding component 180, so as to engage and retain the top surface 181 of the component 180. When in the engaged position, the latch arm 178 acts to retain the component 180. When in an unengaged position, the latch arm 178 allows for an operator to access and remove the corresponding component 180 from the adapter module. As shown by FIG. 1J and FIG. 1K, each of the latch arms 178 may be provided with a raised thickness and a textured surface to facilitate an operator in grasping and moving the individual latch arms 178 between engaged and unengaged positions.

FIG. 1L illustrates a top view of a portion of the circuit board device 160 shown by C-C of FIG. 1H, according to one or more examples. As shown, each of the component latches 176 includes a latch arm 178, a base structure 192 having a fastener receptacle 194 and a rotatable pivot structure 188 that supports a pivot motion of a latch arm 178. Each of the fastener receptacles 194 may be structured to provide, for example, a threaded opening that extends to the circuit board 170, to allow for insertion of a fastener that attaches the component latch 176 to the topside of the circuit board 170. Each latch arm 178 may also include a base segment 179 that joins or otherwise integrates with the pivot structure 188 along a length that partially circumvents the pivot structure 188. In this manner, the structure of the component latch 176 allows for the latch arm 178 to pivot along a range of motion that extends between engaged and unengaged positions. As described in greater detail, each of the component latches 176 can include structures or configurations that limit or constrain the movement of the corresponding latch arms 178 to alternative positions where the latch member is engaged or unengaged.

In some examples, the individual latch arms 178 may be configured to pivot about 180 degrees when manipulated between engaged and unengaged positions. For example, in FIG. 1L, the bottom component latch 176 is shown with latch arm 178 in the engaged position, while the top component latch 176 as its latch arm 178 in the unengaged position. When both latch arms 178 are in the unengaged positions, the component 180 can be removed. Conversely, when the latch arms 178 are in the engaged position, the component 180 is securely retained. More generally, alternative implementations may provide for the latch arms 178 to be pivoted between 170-190 degrees, or even more generally, between 160 and 200 degrees. With further reference to an example of FIG. 1L, an operator may pivot the latch arm 178 by more than 180 degrees in order to move the latch arm from the engaged position to the unengaged position.

FIG. 1M illustrates an isometric view of a component latch, according to one or more examples. As shown, the component latch 176 includes the base structure 192 having fastener receptacle 194 and pivot structure 188. The pivot structure 188 extends upward (in Z direction), from the base structure 192, within a preexisting notch 175 (see FIG. 1J) of the components 180, so that the pivot structure 188 is offset from the base structure 192 in the X and Y directions.

The base segment 179 of the retention arm 178 may extend to join or connect with the pivot structure along an arc length of the pivot structure 188. In this way, the pivot structure 188 rotates within the notch 175 when the latch arm 178 is pivoted above the component 180.

In examples, the latch 176 can include one or more types of clasping mechanisms, stops and/or other structures that guide the rotation of pivot structure, within the confines of the notch 175 and/or as part of the base structure 192. In some examples, the pivot structure 188 include structures or surface features which, in combination with other structures extending from the base structure 192 or elsewhere, control or guide the rotation of the pivot structure 188, and thus the retention arm 178. In some examples, the pivot structure 188 may include a recess 185 or opening that moves circumferentially with rotation of the pivot structure 188. The recess 185 may be configured to receive and retain a tab 187 of the base structure 192. The radial position of the recess 185 may be selected so that the tab 186 engages the recess 185 when the latch arm 178 is in the engaged position. Thus, when the tab 186 is engaged with the recess 185, the pivot structure 188 may fix in position, resulting in the retention arm 178 remaining in the engaged position, so as to retain the corresponding component 180. While an example as described provides for the pivot structure 188 to include recess 185, in variations, the pivot structure can provide the tab 186 to engage an opening, divot or other surface feature of the surrounding base structure 192.

The recess 185 and tab 186 may also be structured to allow for the tab to disengage from the recess with application of a rotational force on the latch arm that is readily achieved by an operator's use of fingers. In this manner, the retention arm 178 can be pivoted through user manipulation by, for example, 180 degrees, such that the retention arm 178 is moved from the engaged position to the unengaged position. Subsequent movement of the retention arm 178 can translate into rotation of the pivot structure 188, which in turn can rotate the recess 185 of the pivot structure 188 back into a position where it is engaged by the tab 186

The pivot structure 188 and/or the base structure 192 may also include additional structures that serve as, for example, stops or guides for the movement of the retention arm 178. For example, one or more stops 184 may be formed on the base structure 192 to prevent the retention arm 178 from rotating beyond a preset range of movement (e.g., no more than 200 degrees between open and closed positions).

As an addition or alternative, the component latches 176 can utilize a biasing element to constrain extension arm 178. For example, the pivot structure 188 can house a spring that biases against rotation to prevent, for example, unintended vibrational forces from moving the extension arm away from the engaged position. Still further, in other variations, the pivot structure 188 can house a ferrule and spring, which combine to prevent rotation of the pivot structure beyond preset limits.

While examples as described provide for component latch 176 to be implemented as part of an adapter module, in variations, the component latch 176 (and variants) can be implemented for other types of computing environments. For example, the component latch 176 can be provided for use in attaching motherboard components, so as to enable an operator to readily engage and disengage a retained component from the motherboard.

Conclusion

Although examples are described in detail herein with reference to the accompanying drawings, it is to be understood that the concepts are not limited to those precise examples. Accordingly, it is intended that the scope of the concepts be defined by the following claims and their equivalents. Furthermore, it is contemplated that a particular feature described either individually or as part of an example can be combined with other individually described features, or parts of other examples, even if the other features and examples make no mentioned of the particular feature. Thus, the absence of describing combinations should not preclude having rights to such combinations.

What is claimed is:

1. An adapter housing assembly comprising:
a bottom housing segment structured to couple to an external device as a first type of component, the bottom housing segment at least partially defining an interior region to retain one or multiple memory components of a second type of component; and
a top housing segment pivotably connected to the bottom housing segment to move between a closed position and an open position, wherein in the open position, the interior region is exposed to allow for the one or multiple components to be accessed and removed.

2. The adapter housing assembly of claim 1, wherein the first type of component is associated with a first form factor, and wherein the second type of component is associated with a second form factor that is different than the first form factor.

3. The adapter housing assembly of claim 2, wherein the first type of component utilizes a first type of connector, and wherein the second type of component utilizes a second type of connector that is different than the first type of connector.

4. The adapter housing assembly of claim 1, further comprising:
a latch mounted to an interior of the bottom housing segment, the latch including a base portion and a latch member, the latch member extending upward from the base portion;
wherein the latch member is structured to latch onto a portion of the top housing segment when the top housing segment is in the closed position.

5. The adapter housing assembly of claim 1, further comprising:
a pair of latch members that oppose one another across a width of the bottom housing segment, each latch member extending upward from the bottom housing segment towards the top housing segment;
wherein each latch member is structured to latch onto a portion of the top housing segment when the top housing segment is in the closed position.

6. The adapter housing assembly of claim 1, wherein the top housing segment is structured as a heat sink.

7. The adapter housing assembly of claim 6, wherein the top housing segment includes an exterior surface having a plurality of surface ridge features.

8. An adapter module comprising:
a bottom housing segment structured to couple to an external device as a first type of component, the bottom housing segment at least partially defining an interior region;
a circuit board positioned within the interior region of the bottom housing segment, the circuit board being structured to retain one or multiple memory components of a second type of component; and
a top housing segment pivotably connected to the bottom housing segment to move between a closed position and an open position, wherein in the open position, the interior region is exposed to allow for the one or multiple memory components to be accessed.

9. The adapter module of claim 8, further comprising:
an electrical interface including an external connector provided on an underside of the bottom segment, wherein the external connector is structured to mate with a connector of a type that is associated with the second type of component.

10. The adapter module of 8, wherein the first type of component is associated with a first form factor, and wherein the second type of component is associated with a second form factor that is different than the first form factor.

11. The adapter module of claim 8, wherein the top housing segment is structured as a heat sink.

12. The adapter module of claim 11, wherein an external surface of the top housing segment includes a plurality of surface features that are structured to dissipate heat generated from within an interior region of the adapter module.

13. The adapter module of claim 8, further comprising:
one or more component latches, each component latch including a latch member that extends over a top side of a corresponding component that is mounted onto the circuit board, wherein each latch member is pivotable over the mounted component to move between an open position and a closed position.

14. A circuit board device comprising:
a circuit board;
a component coupled to the circuit board;
a component latch attached to the circuit board, wherein the component latch includes:
a rotatable pivot structure extending vertically within a slot formed in the component;
a latch arm, including a base segment that joins or attaches to the pivot structure, the latch arm being configured to extend laterally over the component;
wherein the pivot structure includes one or more mechanisms to guide rotation of the pivot structure between a set range that coincides with the latch arm being pivoted between an engaged position and an unengaged position.

15. The circuit board device of claim 14, wherein the component is structured to include a top housing segment that can pivot from a closed position that coincides with the latch being in the engaged position, to an open position that coincides with the latch being in the unengaged position.

16. The circuit board device of claim 15, wherein the component is structured to retain one or more memory components in electrical connection with the circuit board.

17. The circuit board assembly of claim 16, wherein the top housing segment is structured to enable an operator to access and remove or replace the one or more memory components from the component.

18. The circuit board assembly of claim 17, wherein the component includes at least a first connector to mate with at least one memory component that is retained by the component.

19. The circuit board assembly of claim 18, wherein the component includes a bottom housing segment, and the bottom housing segment includes a second connector that mates with the circuit board.

20. The circuit board assembly of claim 19, wherein the first connector is of a first type and the second connector is of a second type, and wherein the first type is different than the second type.
